(19) United States
(12) Patent Application Publication
(10) Pub. No.: US 2012/0097330 A1
(43) Pub. Date: Apr. 26, 2012

(54) DUAL DELIVERY CHAMBER DESIGN

(75) Inventors: Prahallad Iyengar, Mountain View, CA (US); Sanjeev Baluja, Campbell, CA (US); Dale R. DuBois, Los Gatos, CA (US); Juan Carlos Rocha-Alverez, San Carlos, CA (US); Thomas Nowak, Cupertino, CA (US); Scott A. Hendrickson, Brentwood, CA (US); Yong-Won Lee, San Jose, CA (US); Mei-Yee Shek, Palo Alto, CA (US); Li-Qun Xia, Cupertino, CA (US); Derek R. Witty, Fremont, CA (US)

(73) Assignee: Applied Materials, Inc., Santa Clara, CA (US)

(21) Appl. No.: 12/908,617

(22) Filed: Oct. 20, 2010

(51) Int. Cl. H01L 21/465; H01L 21/46

(52) U.S. Cl. 156/345.34; 118/715; 118/723 R; 118/724; 118/723 E

(57) ABSTRACT

A substrate processing system includes a thermal processor or a plasma generator adjacent to a processing chamber. A first processing gas enters the thermal processor or plasma generator. The first processing gas then flows directly through a showerhead into the processing chamber. A second processing gas flows through a second flow path through the showerhead. The first and second processing gases are mixed below the showerhead and a layer of material is deposited on a substrate under the showerhead.

### BACKGROUND

1. Field of Invention

The present invention relates to semiconductor wafer processing systems and, more particularly, to a gas distribution showerhead for supplying at least two process gases to a reaction chamber of a semiconductor wafer processing system.

2. Description of the Related Art

Semiconductor wafer processing systems generally contain a process chamber having a pedestal for supporting a semiconductor wafer within the chamber proximate a processing region. The chamber forms a vacuum enclosure defining, in part, the process region. A gas distribution assembly or showerhead provides one or more process gases to the process region. The gases can be heated and/or supplied with RF energy which causes the molecules to disassociate. The process gases can then be mixed and used to perform certain processes on the wafer. These processes may include chemical vapor deposition (CVD) to deposit a film upon the wafer or etching to remove material from the wafer. In some embodiments, the process gases can be energized to form a plasma which can perform processes upon the wafer such as plasma enhanced chemical vapor deposition (PECVD) or plasma etching.

In processes that require multiple gases, generally the gases are combined within a mixing chamber that is remote from the processing chamber and coupled to the showerhead via a conduit. The gaseous mixture then flows through a conduit to a distribution plate, where the plate contains a plurality of holes such that the gaseous mixture is evenly distributed into the process region. As the gaseous mixture enters the process region, the energized particles and/or neutral radicals cause a layer of material to be deposited on the wafer in a CVD reaction.

Although it is generally advantageous to mix the gases prior to release into the process region to ensure that the gases are uniformly distributed into the process region, the gases tend to begin reduction, or otherwise react within the mixing chamber. Consequently, deposition or etching of the mixing chamber, conduits and other chamber components may result prior to the gaseous mixture reaching the process region. Additionally, reaction by products may accumulate in the chamber gas delivery components. In an effort to maintain the gases in separate passageways until they exit the distribution plate into the process region, some showerheads maintain two gases in separate passageways until they exit the distribution plate into the process region. By using separate passageways, the gases do not mix or react with one another until they reach the process region near the wafer.

In some applications, one of the precursor gases can be neutral radicals produced in a remove processing chamber. The neutral radicals can be produced by a remote thermal or plasma processing chamber. The neutral radicals can flow from the remote chamber through a conduit to the showerhead and through a first set of distribution outlets of the showerhead into the processing chamber above the wafer substrate. Simultaneously, a second precursor gas can flow from a source through a second set of outlets from the showerhead. The neutral radicals can then mix with the second precursor gas and provide the desired chemical reaction above the substrate. A problem with a remote plasma source is that a large percentage, possibly 80%, of the neutral radicals are recombined before reaching the wafer processing chamber.

In other embodiments, a remote plasma source can be used. The plasma gas can flow through a conduit to the showerhead. The plasma can flow through a first set of outlets of the showerhead into the processing chamber above the wafer substrate. Simultaneously, a second precursor gas can also flow through a second set of outlets from the showerhead. The plasma can then mix with the precursor gas and provide the desired chemical reaction above the substrate. Again, the problem with a remote plasma source is that a large percentage of the charged species produced by the plasma are recombined before reaching the wafer processing chamber.

Therefore, there is a need in the art for a system that is capable of providing a much higher percentage of neutral radicals or plasma to a substrate and conveys at least two gases into a process region without commingling the gases prior to reaching the process region.

### SUMMARY OF THE INVENTION

The invention is directed towards a CVD processing chamber that includes an antechamber that is directly adjacent to the CVD processing chamber. The antechamber can perform processing on the process gases before they enter the CVD processing chamber. In an embodiment, the antechamber is a modular structure that can be configured to perform various different processes. The antechamber can be a thermal processing chamber that can include a heater. The heaters can perform thermal processing on a precursor gas. For example, a precursor gas can enter the antechamber and thermal disassociation can be performed on the process gas producing charged species and neutral radicals. The neutral radicals can then flow through the showerhead into the substrate processing chamber.

In other embodiments, the antechamber can include a plasma generator. Various types of plasma generators can be used including: capacitively coupled, inductively coupled, optical or any other suitable types of plasma generator. Because the plasma generator is directly over the showerhead and the processing chamber containing the substrate and pedestal are directly under the showerhead, the loss of charged species is minimized.

In an embodiment, the plasma generator can include a precursor gas manifold, a gas box, a blocker plate and a spacer ring. The manifold can be mounted over the gas box and the blocker plate can be mounted under the gas box. The plasma generator chamber can be defined by the lower surface of the blocker plate, the upper surface of the showerhead and the inner diameter of the spacer ring. The blocker plate and upper surface of the showerhead function as electrodes. An RF power source is coupled to the blocker plate and the face place is grounded.

In an embodiment, the showerhead includes separate flow paths for two processing gases. A first flow path can include a first array of inlet holes that extend vertically through the showerhead from the plasma generator to a first array of outlet holes in the processing chamber. The second flow path through the showerhead can include a second set of inlets and a second flow path that direct the second processing gas horizontally through the showerhead to a second array of vertical outlet holes into the processing chamber. The first array of outlet holes can be mixed with the second array of outlet holes so that after the first and second processing gases flow through the shower head they are mixed at the top of the processing chamber prior to contact with the substrate mounted on the pedestal.

The configuration of the plasma generator directly above the showerhead improves the percentage of reactive gases that enter the processing chamber which can be neutral radicals or charged particles. Thus, a much higher percentage of neutral radicals or charged particles enter the processing chamber in comparison to a remote plasma source. Since the efficiency of the system is greatly enhanced, a much lower number of neutral radicals or charged particles need to be produced to perform the required wafer processing.

In different embodiments, the plasma generator can be configured with different spacer rings depending upon the application of the processing chamber. For example, the spacer ring can act as a thermal conductor and/or RF isolator depending upon the material used. These different configurations can depend upon the processes being performed by the processing chamber.

The gas box can include a thermal heating unit. In an embodiment, the gas box can be heated to 160° C. using a gas box heater. This heat can be isolated from the faceplate or transferred to the faceplate depending upon the spacer material. If thermal isolation is desired, the spacer ring can be made of a thermally insulative ceramic such as alumina. Conversely, heat needs to be transferred to the faceplate by using a spacer ring made of a thermally conductive material such as aluminum or stainless steel.

In another embodiment, the spacer ring can include a heater. The heater ring can include a heating element that is embedded into the ring. A temperature sensor can also be coupled to the heater so that the heat produced by the ring can be regulated. The heating element can heat the faceplate to about 200° C. or higher.

The inventive processing system can be used for “cold” processing of substrates where the substrate is kept less than 100° C. The cooler processing temperature prevents any thermal damage of the substrate. The processor can keep the substrate cool by keeping the RF energy away from the substrate. The RF energy is isolated from the substrate by the faceplate. A temperature controlled pedestal is disclosed in copending U.S. patent application Ser. No. 12/641,819, Multifunctional Heater/Chiller Pedestal For Wide Range Wafer Temperature Control filed Dec. 18, 2009, which is hereby incorporated by reference.

The processing chamber can operate in a range of processing conditions. The flow rates of the precursor and oxidizer can be between about 10 to 40 standard liters per minute (SLM). The temperature range can be between about 30° C. to 200° C. The pressure range can be about 2 to 100 Torr.

These operating conditions can be particularly suited for certain low temperature processing steps. For example, a low temperature SiO liner can be deposited on a patterned photoresist layer. The deposition temperature must be very low to avoid damage to the photoresist material. In this application the temperature can be less than 100° C. In these embodiments, a cooling fluid can be passed through the pedestal to maintain the pedestal and substrate processing temperature between about 50° C.-100° C.

In other embodiments, the processing chamber can be used for thermal and/or plasma processing. The pedestal can include a heater that heats the substrate and the processing chamber which can cause thermal reactions within the processing chamber. In the plasma mode, the showerhead is electrically separated from the pedestal by a dielectric isolator. The RF power is applied between the pedestal and the showerhead to generate the plasma within the processing chamber.

### BRIEF DESCRIPTION OF THE DRAWINGS

FIG. 1 illustrates a cross sectional view of a processing system;

FIG. 2 illustrates a cross sectional view of a processing system with processing gas flow indicated;

FIG. 3 illustrates a cross sectional view of the upper gas distribution plate of the showerhead;

FIG. 4 illustrates a top view of the upper gas distribution plate of the showerhead;

FIG. 5 illustrates a cross sectional view of the lower gas distribution plate of the showerhead;

FIG. 6 illustrates a top view of the lower gas distribution plate of the showerhead;

FIG. 7 illustrates a control system for controlling the heat produced by the heater;

FIG. 8 illustrates a heat flow path blocked by the spacer ring;

FIG. 9 illustrates a heat flow path through the spacer ring;

FIG. 10 illustrates a heat flow path from a heater in the spacer ring;

FIG. 11 illustrates embodiments of the outlet holes of the showerhead.

### DETAILED DESCRIPTION

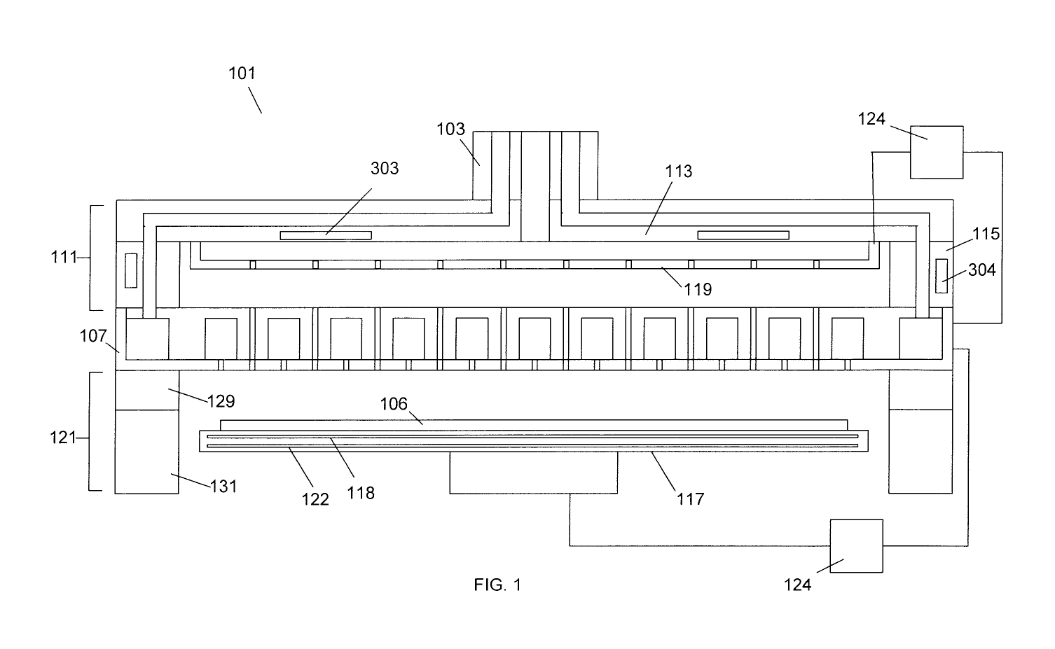

The present disclosure is directed towards a modular precursor gas processing system that is used for chemical vapor deposition (CVD). With reference to FIG. 1, a cross sectional view of an embodiment of the CVD processing system 101 is illustrated. The plasma processing system 101 includes an antechamber 111, a processing chamber 121 and the showerhead 107 that separates the antechamber 111 from the processing chamber 121. The system 101 also includes a manifold 103, a gas box 113, a spacer ring 115, a blocker plate 119, a pedestal 117, an isolator 129 and a body 131.

A substrate 106, such as a semiconductor wafer, is maintained proximate the processing chamber 121 upon the pedestal 117. The pedestal 117 may be able to move vertically within the processing chamber 121 to lower the pedestal 117 to a position that allows a substrate 106 to be inserted or removed from the processing chamber 101 through a slit valve (not shown) while in the lowered position. When the pedestal 117 is in the lower position, a new substrate 106 is positioned upon the pedestal 117 and raised into a process position, which places the substrate 106 proximate the process region.

In an embodiment, the pedestal 117 may include a heater 118 and/or a cooling mechanism 122. U.S. patent application Ser. No. 12/641,819, Multifunctional Heater/Chiller Pedestal For Wide Range Wafer Temperature Control filed Dec. 18, 2009 is hereby incorporated by reference and discloses additional details about embodiments of pedestals that include the heater 118 and cooling mechanism 122. The heater 118 and cooling mechanism 122 can be used to maintain the substrate 106 at any desired temperature.

Process gases are supplied through the showerhead 107. In the preferred embodiment of the invention, a plurality of gases are used to process the substrate 106. These gases form a gaseous mixture that is required to process the wafer, i.e., form a deposit on the wafer or chemically etch the substrate 106. In an embodiment, the distance between the bottom surface of the showerhead 107 and the upper surface of the substrate 106 can be about 0.2-2.0 inches. This distance can be adjusted to optimize the mixing of the process gases. The processing chamber 121 can configured to function as a thermal processor or as a plasma chamber. In the thermal processing mode, the isolator 129 can be made of a thermally conductive material that is also electrically conductive, such as a metal material. In the plasma chamber configuration, the isolator 129 can be made of a dielectric material the electrically separates the showerhead 107 from the pedestal 117. RF electrical power from a power supply 124 can be applied between the pedestal 118 which can be coupled to the conductive body 131 and the showerhead 107. For example, an RF power supply can be coupled to the showerhead 107 and the pedestal 118 can be grounded. The electrical field can energize gases within the processing chamber 121 into a plasma.

The antechamber 111 can be a modular structure that can be configured to perform various processes. In an embodiment, the antechamber 111 can be a thermal processing unit. In other embodiments, the antechamber 111 can be a plasma generator. Because the antechamber 111 design can be modular, the antechamber 111 can be removed and replaced to perform a different function as needed by the user.

In an embodiment, the antechamber 111 is a thermal processing unit that includes one or more heaters 303, 304. When heated some precursor gases can disassociate producing neutral radicals that can be used to process the substrate. The heating temperature can depend upon the process gas disassociation temperature. In an embodiment, the thermal processing unit can be heated to about 550° to 600° C. or higher. In other embodiments, various other processes can be performed in the antechamber to produce neutral radicals. For example, the antechamber may include optical energy sources that are used to disassociate the precursor gases. If the precursor gas is ozone, the exposure of the ozone to 185 nm or 254 nm wavelength light can result in the production of oxygen radicals.

In an alternative embodiment, the antechamber 111 includes a plasma generator that can be capacitively coupled to the bottom surface of the blocker plate 119 and the upper surface of the showerhead 107 which each function as electrodes. The blocker plate 119 can be coupled to an RF power source and the showerhead 107 can be electrically grounded. The plasma generator antechamber 111 volume is surrounded by a spacer ring 115. Because the spacer ring 115 separates the blocker plate 109 from the showerhead 107, in this embodiment, the spacer ring 115 is electrically insulative. In other embodiments, the antechamber 111 can include other types of energy sources to produce plasma including: inductive coils 112 or any other suitable energy source.

During operations, the first processing gas can flow through the manifold 103 into a volume above the blocker plate 119. The first processing gas is distributed across the width of the antechamber 111 by the blocker plate 119 and flows through holes into the antechamber 111. The RF power produces an AC electrical field between the blocker plate 119 and the showerhead 107. The atoms of the first process gas are ionized and release electrons that are accelerated by the RF field. The electrons can also ionize the first process gas directly or indirectly by collisions, producing secondary electrons. The electric field can generate an electron avalanche producing an electrically conductive plasma due to abundant free electrons.

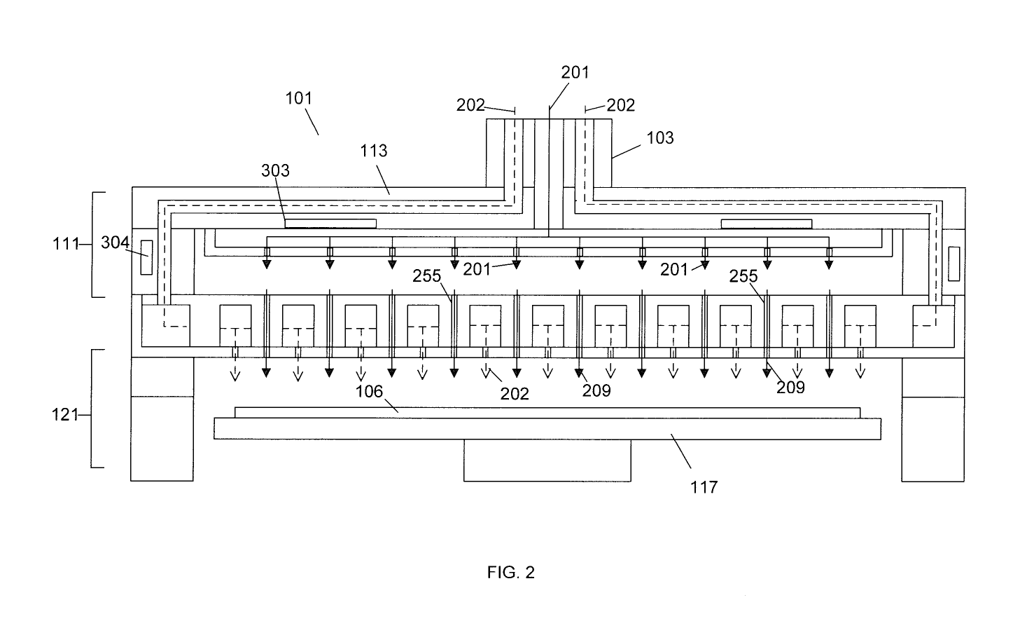

With reference to FIG. 2, a cross section of the substrate processing system 101 is illustrated with the flow paths of the first processing gas 201 and the second process gas 202 are illustrated. The first processing gas 201 flows through the manifold 103 and vertically through the gas box 113 to the blocker plate 119 that distributes the first process gas 201. The first process gas 201 flows through the blocker plate 119 into the antechamber 111. In an embodiment, thermal processing is performed on the first process gas 201 producing ions and neutral radicals 209. The neutral radicals 209 flow through the vertical holes 255 in the showerhead 107 into the processing chamber 121.

The second processing gas 202 can flow through the manifold 103 and the gas box 113. The second processing gas 202 can then flow through the spacer ring 115 to the shower head 107. The second processing gas 202 can enter the showerhead 107 at multiple locations close to the outer diameter and flow horizontally through the showerhead 107 through a flow path that is separated from the neutral radicals 209 flow path. Thus, there is no contact between the neutral radicals 209 and the second processing gas 202 within the showerhead 107. The second process gas 202 exits the showerhead 107 through an array of holes 255 at the bottom surface where the neutral radicals 209 mix with the second process gas 202. The reaction of the mixed process gases 202, 209 can deposit a layer of material on the substrate 106 placed on the pedestal 117. Because the thermal processor is very close to the processing chamber 121, very little neutral radicals 209 are lost before they reach the processing chamber.

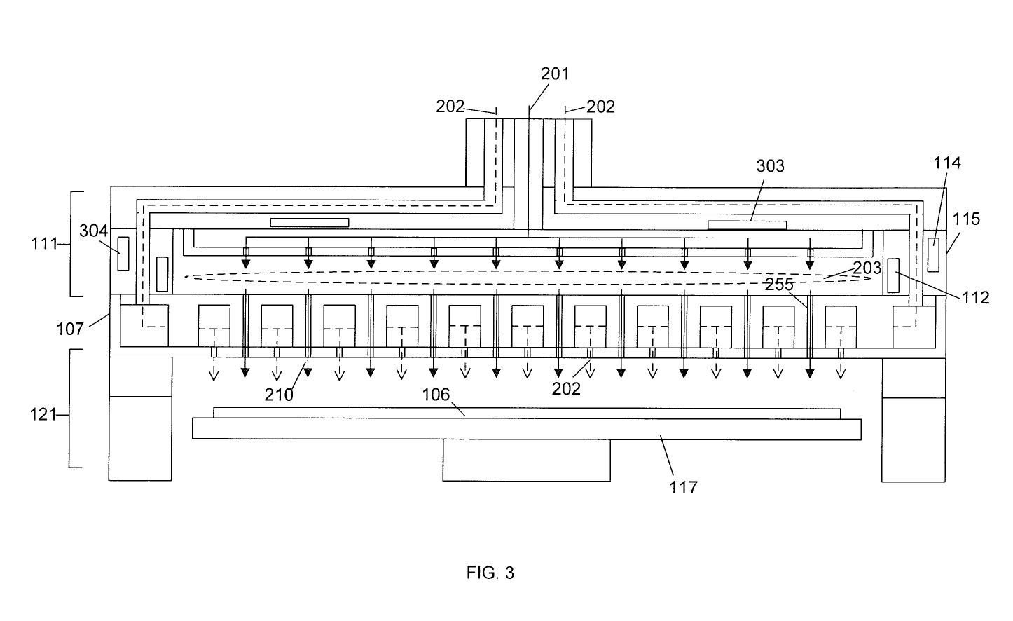

With reference to FIG. 3, in an embodiment the antechamber 111 includes a plasma generator. In this embodiment, the first processing gas is energized into a plasma 203. The charged species 210 produced by the plasma can flow through the vertical holes 255 in the showerhead 107 to the processing chamber 121 where the charged species 210 are mixed with the second processing gas 202. The reaction of the charged species 210 and the second processing gas can cause the deposition of a layer of material on the substrate 123. In an embodiment, the plasma generator can be a capacitively coupled and may generate an electrical field produced between the blocker plate 119 and the showerhead 107. In other embodiments, the plasma generator can be inductively coupled and may include induction coils 114 in the spacer ring 115.

In an embodiment, the vertical holes 255 can have a “length to width aspect ratio” that is greater than 5:1. Because the holes 255 are much longer than their widths, the plasma 203 cannot pass through these holes 255. For example, the length to width ratio may be greater than about 5:1. Thus, the first process gas charged species 209 enters the processing chamber 121 and the substrate 106 will not be exposed to a plasma or active radicals such as O, O₂, Cl or OH plasma. This feature of the processing chamber may be applicable to some processing methods where the antechamber 111 is a plasma generator. In other embodiments, the length to width aspect ratio of the holes 255 can be less than 5.

Because the plasma generator antechamber 111 is positioned very close to the processing chamber 121, many more charged species 209 reach the processing chamber 121 than with a remote plasma source. The percentage of charged species 209 reaching the processing chamber 121 can be greater than 80%. In contrast, it is estimated that as little as 20% of the plasma produced by a remote plasma source reaches the processing chamber before being deionized. Thus, the plasma processing system 101 is more efficient than a remote plasma processing system.

In addition to the charged species 209 from the first processing gas 201, the substrate 123 is also processed with a second process gas 202. In an embodiment, the second processing gas 202 flows through the manifold 103 and the spacer ring 115 before entering the faceplate 107. Although, the drawings illustrate two holes formed through the spacer ring 115, several additional holes can be evenly spaced around the spacer ring 115. In an embodiment, the second processing gas 202 can remain deionized. In order to avoid ionization, the hole design through the spacer ring 115 can have a high aspect ratio that acts as a RF scrubber and prevents ionization of the first processing gas. In an embodiment, the holes through the spacer ring 115 for the second processing gas 202 can have an aspect ratio of 5:1 or greater. These holes can be between about 0.020 to 1.20 inches in diameter and the lengths of the holes can range from about 0.100 to 6.00 inches. In other embodiments, the aspect ratio of holes through the spacer ring 115 can be less than 5:1.

The second process gas 202 flows from the spacer ring 115 and into the showerhead 107. The second processing gas 202 can flow horizontally through the interior volume of the showerhead 107 and out of the lower surface of the showerhead 107 through an array of holes through which the second processing gas 202 flows into the processing chamber 121. In an embodiment, the showerhead 107 has a special design that allows two processing gases to flow through the showerhead 107 without mixing within the showerhead 107. The showerhead 107 contains two components, a lower gas distribution plate 148 and an upper gas distribution plate 150. These two plates 148, 150 contain various channels and holes that define two distinct passageways for the two process gases 202, 210 to enter the process chamber 121.

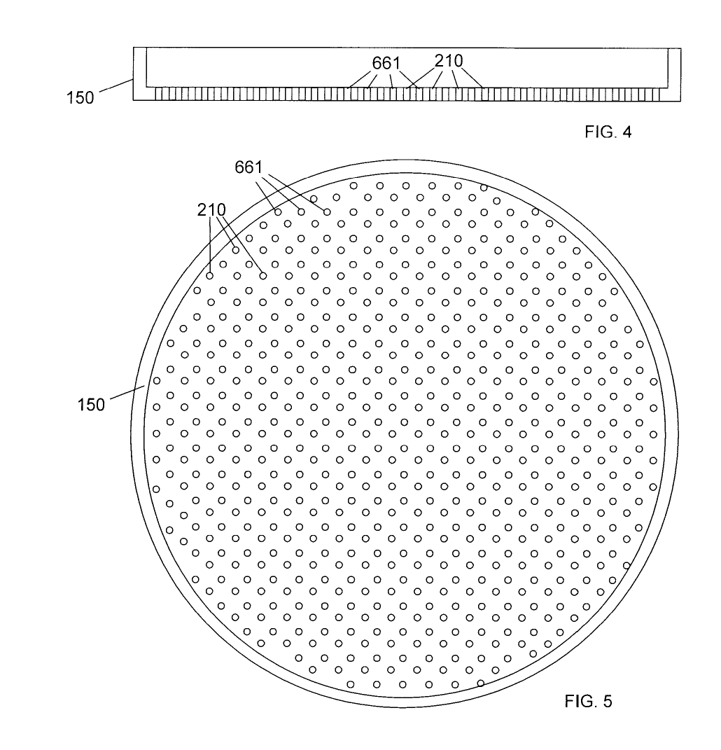

Examples of the showerhead 107 components are illustrated in FIGS. 4-7. In order to seal the channels and holes to isolate the first and second process gases, the lower and upper gas distribution plates 148, 150 can be fused to one another to form a unitary showerhead 107. The fusing can be performed by brazing, welding, adhesives or any other suitable fusing process. In other embodiments, the lower and upper gas distribution plates 148, 150 can be coupled together and seals such as metal or o-ring seals can be used to seal the channels and holes of the showerhead 107 to separate the different gas flow paths. The lower and upper gas distribution plates 148, 150 can be made of various different materials including: aluminum, aluminum alloys, stainless steel and other suitable materials.

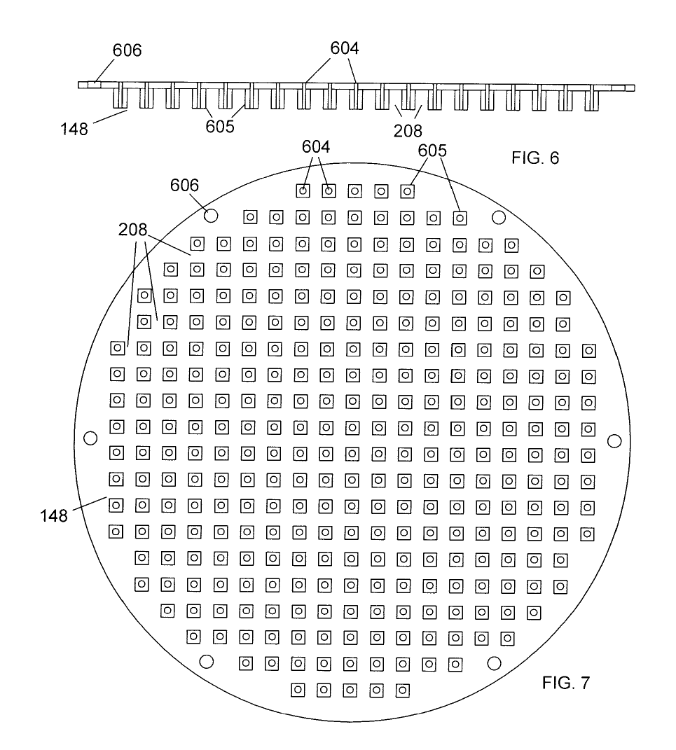

FIG. 4 illustrates a cross sectional view of an embodiment of the lower gas distribution plate 150 of the showerhead. FIG. 5 illustrates a top plan view of an embodiment of the lower gas distribution plate 150. FIG. 6 provides a cross sectional view of an embodiment of the upper gas distribution plate 148 and FIG. 7 illustrates a bottom view of an embodiment of the upper gas distribution plate 148. The upper gas distribution plate 148 contains a plurality of holes 604 having a diameter of approximately 1.6 mm and extend through posts 605. These holes 604 are aligned with the bores 210 in the lower gas distribution plate 148. The lower gas distribution plate 148 also includes a plurality of holes 661 are used to distribute the second processing gas from the channels 208 between the posts 605 out the bottom of the showerhead 107. In an embodiment, there are approximately 600 to 2,000 holes in the upper gas distribution plate 148 which match identically to the arrangement of the first gas holes 206 and their associated counterbores 210 in the lower gas distribution plate 148. The gas distribution holes 606 that provide gas to the channels 208 in the lower gas distribution plate 148 are arranged about the periphery of the upper gas distribution plate 150 such that there are 8 holes, each having a diameter of about 0.125 to 0.375 inch.

To assemble the showerhead 107, the lower 148 and upper 150 distribution plates can be fused together. In an embodiment, the lower 148 and upper 150 distribution plates are clamped to one another, and the assembly is placed into a furnace where the gas distribution plates 148, 150 brazed to each other. In other embodiments, elastomer or metal O-rings can be used to retain the gas within the faceplate 130 or to maintain separation of the gases.

The bottom 148 and top 150 plates are fused at the junction of the flange 202 and flange support 600. In addition, the plates 148 and 150 join at the surfaces 608 adjacent the tops of holes 204 and 206. Specifically, the flange 202 and the flange support 600 fuse at the outer edge 902 forming a sufficient seal to maintain all of the gases inside the showerhead. Additionally, the upper gas distribution plate 150 and the flange 202 of the lower gas distribution plate 148 form a circumferential plenum 900 that provides gas to the gas channels 208 formed in the lower gas distribution plate 148. The upper gas distribution plate 150 forms the tops of the channels 208 such that uniform rectangular cross section channels 208 are formed to distribute the second process gas to the holes 204 in the lower gas distribution plate 148. The holes 604 in the upper gas distribution plate 150 are aligned with the holes 210 in the lower gas distribution plate 148 to allow the first process gas to pass through both distribution plates 148 and 150 unimpeded to reach the process region of the processing chamber.

In other embodiments, other showerhead configurations are possible. For example, the showerhead may have planar upper and lower plates. The upper plate can have holes for the first process gas and the lower plate can have holes for the first process gas and the second process gas. As illustrated in FIGS. 1-6, the holes for the first process gas extend through columns of the upper plate that contact the top of the lower plate. In other embodiments, columns between the upper and lower surfaces of the showerhead can be made of a different material such as ceramic, metal or other suitable materials that can reduce the recombination of the neutral radicals or charged species.

With reference to FIG. 1, in an embodiment, the substrate processing system 101 can also be configured to heat the processing gases and substrate. In an embodiment, heaters 303 are coupled to the gas box 113. As the second process gas 202 flows through the gas box 113, the heater 303 heats the gas. In an embodiment, the gas box 113 can heat the second process gas 202 up to about 120° C. to 180° C., or any other suitable temperature. Additional heaters 304 can be mounted in the spacer ring 115 around the antechamber 111. The heaters 304 can heat the antechamber 111 up to a temperature of about 120° C. to 180° C., or any other suitable temperature.

The heaters 303, 304 and 118 can be an electrical resistance heaters which converts electrical energy into heat and transmits the heat by conduction and convection. The heaters 303, 304 and 118 can include an electrical resistor and an electrical voltage can be applied across the resistor to generate heat. In an embodiment, the temperature can be regulated by one or more controllers that are coupled to the heaters and a temperature sensor. A set temperature can be input to the controller and the power to the heater 303, 304 and 118 can be regulated to maintain the set temperature. Temperature sensors can detect the actual temperature of the processing chamber around the heaters 303, 304 and 118 such as the gas box 113, antechamber 111 and pedestal 117. The detected temperatures can be transmitted to the controller which can then adjust the power to the heaters 303, 304 and 118 to maintain the required set temperatures. The power used by the heaters 303, 304 and 118 can be electrical power that is supplied by an electrical power source.

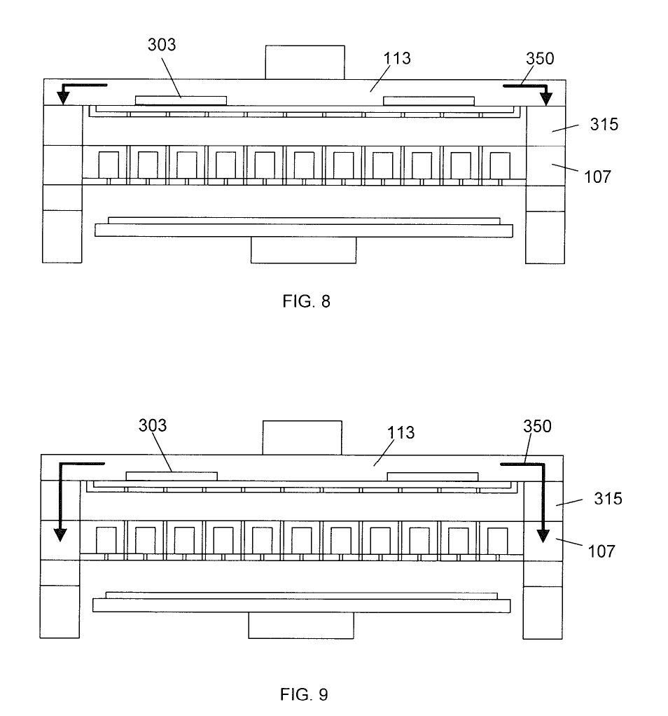

In an embodiment, it may be desirable to isolate the heat produced by the heater 303 to only the gas box 113 and prevent the heat from being transferred to the other components of the plasma processing system 101. The gas box 113 can be in direct contact with the spacer ring 115 and if the spacer ring 113 is made of a thermally insulative material, the heat of the gas box heater 303 will not be transferred to the showerhead 107. With reference to FIG. 8, in other embodiments, the spacer ring 115 can be made of a thermally insulative material. The heater 303 heats the gas box 113 to a temperature of about 120° C. to 180° C. However, the insulative properties of the spacer ring 115 prevent the heat 350 from being transferred from the gas box 113 to the showerhead 107. Thus, in this configuration, the showerhead 107 can be substantially cooler than the gas box 113. An example of a thermally isolated spacer ring materials include ceramics such as alumina. Since the heat is transferred from the heater 303 through the gas box 113 and spacer ring 115 to the showerhead 107, the gas box 113 will typically be hotter than the showerhead 107. By keeping the showerhead cooler than the gas box, the second process gas may not decompose prematurely. More specifically, the second process gas may flow through the cooler showerhead and enter the processing chamber in its original state. The second process gas can then react with the neutral radicals or charged species from the first process gas. This reaction can result in a chemical vapor deposition of a material layer on the substrate.

In other embodiments, it can be desirable for the heat produced by the heater 303 to be transferred to other portions of the plasma processing system 101. With reference to FIG. 9, if the spacer ring 115 is made of a thermally conductive material, the heat 350 will be transferred from the gas box 113 through the spacer ring 115 to the showerhead 107. Examples of thermally conductive and dielectric materials include AIN and graphite. In other embodiments, the spacer ring 115 can be made of other materials that have good thermal conductivity and good dielectric or RF isolator characteristics. By heating the showerhead, the second process gas can be heated which results in a decomposition into charged species before the second process gas exits the showerhead. The charged species from the second process gas ions may react with the neutral radicals or charged species from the first process gas. This reaction between the ions of the first process gas and the ions of the second process gas can result in a chemical vapor deposition of a layer on the substrate.

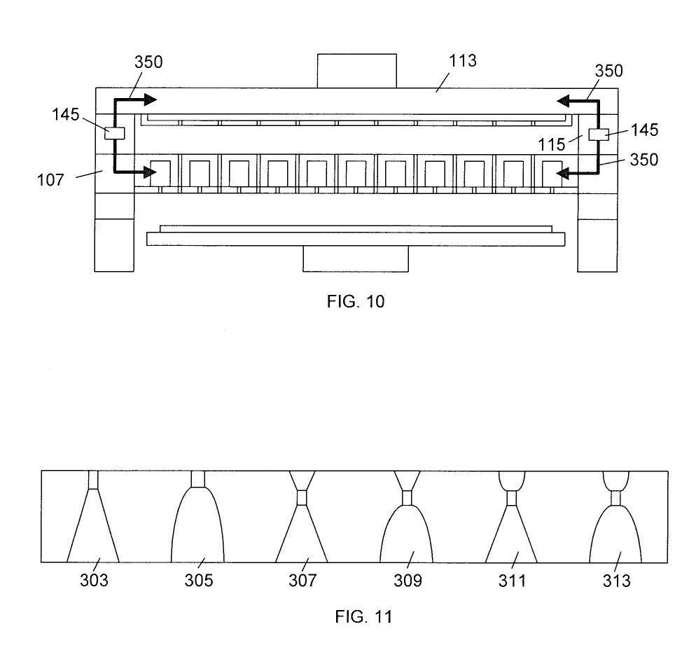

In another embodiment, with reference to FIG. 10, the spacer ring 115 can include an embedded heating element 145. The heat 350 produced by the heater 145 can be transferred to both the gas box 113 and the showerhead 107. Because the heater 145 is located between the gas box 113 and the showerhead 107, the heat can be more evenly distributed to these components. In an embodiment, the heater 145 can heat the spacer ring 115 to about 180° C. to 220° C. As discussed above with reference to FIG. 7, in an embodiment the heater 145 can be coupled to a controller and a temperature sensor to maintain the spacer ring 115 at the desired temperature setting.

In yet another embodiment, it is possible to use an electrically conductive material for the spacer ring 115. In this embodiment, the plasma generator antechamber 111 will not be used to energize the first process gas since the blocker plate 119 will be shorted to the face plate 107 and there cannot be an electric field between the blocker plate 119 and the face plate 107. However, the heating of the process gases by the gas box heater 303 and/or the spacer ring heater 304 can be controlled as described above with reference to FIGS. 8-10 and the system can be used as a CVD processing chamber without plasma. Examples of electrically conductive and thermally conductive spacer ring materials include aluminum, stainless steel and other materials.

By using heaters and different spacer ring materials, the plasma processing system 101 can be configured in various different ways to provide the necessary processing of the first and second processing gases. The configuration of the processing system 101 can depend upon the substrate processing that will be performed.

In an exemplary application, the processing system can be used for a two step deposition process. With reference to FIG. 1, in this application the lidstack portion of the processing chamber can be made of aluminum alloy 6061 and the spacer ring 115 can be conductive so that the antechamber 111 does not function as a plasma generator. A ceramic isolator 129 can be placed between the showerhead 107 and the body 131 for RF isolation so that an electrical charge can be applied between the showerhead 107 and the pedestal 117 and a plasma can be generated in the processing chamber 12. In the first seasoning step, about 200-1000 mg/min of TEOS and 5-10 slm of O₂ flow through both the channels of the antechamber 111 and the showerhead 107. RF power is applied between the showerhead 107 and the pedestal 117 at multiple powers and frequencies. For example, 1,000 Watts at a high frequency RF power and 400 Watts of low frequency power can be applied to the processing chamber 121. The TEOS and O₂ can be energized into a plasma for seasoning the processing chamber 121.

After seasoning, a second main deposition step can be performed. The RF power can be removed so that the processing chamber 121 can be used for a thermal reaction. The first processing gas can be bis(diethylamino)silane (BDEAS) SiH₂(NEt₂)₂ in a helium carrier flows through the blocker plate 119 and the antechamber 111. The BDEAS flow rate can be about 2,000 mg/min. The second process gas can be ozone that has a flowrate of about 10 standard liters per minute (slm) at 5% by weight. The process gases can flow through separate channels through the manifold 103, the gas box 113, the antechamber 111 and the showerhead 107. The processes gases can then be mixed below the shower head 107. The processing chamber 121 and pedestal 117 may be maintained at a temperature of about 50-100° C. causing a thermal reaction between the BDEAS and ozone. The thermal reaction can deposit a layer of SiO on the substrate 106. For this example, the deposition uniformity can be less than 1%.

In a second exemplary application, another two step deposition process is described. In the first step, the processing system can be used for plasma enhanced chemical vapor deposition (PECVD) of a silicon oxide layer in a main deposition step and in the second step, a TEOS cap is deposited on the silicon oxide layer. With reference to FIG. 1, the spacer ring 115 can be made of a dielectric material so that the antechamber 111 can function as a plasma generator. In the main SiO deposition step, the first processing gas can be ozone with a flowrate of about 10 standard liters per minute (slm) at 5% by weight into the antechamber 111 chamber. RF power can be applied between the gas box 119 and the upper surface of the showerhead 107. In an embodiment, the RF power can be 1,000 W at a high frequency and 400 W at a low frequency. The plasma produces neutral oxygen radicals that flow through the showerhead 107. The second processing gas can be BDEAS and helium which flow through a second channel of the showerhead 107. The neutral oxygen radicals can react with the BDEAS and deposit a layer of SiO on the substrate.

After the SiO layer has been deposited, the TEOS cap can be deposited in a second processing step. TEOS and ozone can flow through the antechamber 111 as power is applied between the gas box 119 and the upper surface of the showerhead 107. Process gases can then flow through the showerhead and deposit a TEOS cap on the silicon oxide layer on the substrate 106. For this application, the gas box temperature can be about 100-140° C. and the substrate temperature may be about 100-200° C.

In other embodiments, the processing system 101 can be used with different processing gases and operating conditions for various other types of substrate processing. In particular, the temperatures of the antechamber and processing chamber can be individually controlled. In an embodiment, both the antechamber and processing chamber are kept below about 150° C. In other embodiments, the antechamber can be used for thermal processing and have a much hotter operating temperature. For example, the antechamber can about 400-600° C. The processing chamber can also be maintained at a similar high temperature of 400-600° C. In still other embodiments, the antechamber can be heated to a temperature that is much hotter than the processing chamber or conversely, the antechamber can be much cooler than the processing chamber.

In the prior figures, the outlet holes of the showerhead 107 have been shown as being straight holes for simplicity. However, in other embodiments, the outlet holes have different shapes. For example, with reference to FIG. 11, various outlet hole geometries 305-313. Outlet hole 305 has a narrow upper portion and a conical lower portion. The outlet hole 306 has a narrow upper portion and a concave elliptical lower portion. The outlet hole 307 has an inverted conical upper portion, a narrow cylindrical center portion and a conical lower portion. The outlet hole 309 has an inverted conical upper portion, a narrow cylindrical center portion and a concave elliptical lower portion. The outlet hole 311 has a concave elliptical upper portion, a narrow cylindrical center portion and a conical lower portion. The outlet hole 313 has a concave elliptical upper portion, a narrow cylindrical center portion and a concave elliptical portion.

It will be understood that the inventive system has been described with reference to particular embodiments, however additions, deletions and changes could be made to these embodiments without departing from the scope of the inventive system. Although the systems that have been described include various components, it is well understood that these components and the described configuration can be modified and rearranged in various other configurations.

What is claimed is:

1. An apparatus comprising:
a thermal chamber having a gas box in communication with an internal volume of the thermal chamber and a spacer ring coupled to the gas box;
a showerhead having an upper surface and a lower surface, the showerhead having a first array of holes that extend from the upper surface to the lower surface, the showerhead is adjacent to the thermal chamber and the upper surface of showerhead is a lower surface of the thermal chamber;
a processing chamber, the lower surface of the showerhead is an upper surface of the processing chamber; and
a pedestal within the processing chamber for supporting a substrate adjacent to the lower surface of the showerhead.

2. The apparatus of claim 1 further comprising:
an RF power source coupled to the lower surface of the showerhead;
wherein the pedestal is grounded.

3. The apparatus of claim 1 wherein the pedestal further comprises a cooling mechanism for keeping a substrate placed on the pedestal below 100° C. during processing.

4. The apparatus of claim 1 wherein the spacer ring is thermally conductive.

5. The apparatus of claim 1 wherein the spacer ring is thermally insulative.

6. The apparatus of claim 1 further comprising:
a heater coupled to or embedded within the spacer ring.

7. The apparatus of claim 1 further comprising:
a heater coupled to the thermal chamber.

8. The apparatus of claim 1 wherein the thermal chamber includes a blocker plate that distributes the first process gas in the thermal chamber.

9. The apparatus of claim 1 wherein the showerhead includes an internal volume between the upper surface and the lower surface, an inlet hole to the internal volume and a second array of holes in the lower surface for the second process gas to flow to the processing chamber.

10. The apparatus of claim 1 wherein the showerhead includes a plurality of raised columns that each have a through hole that is aligned with the first array of holes that extend from the upper surface to the lower surface.

11. The apparatus of claim 10 wherein the plurality of raised columns is made of a ceramic material.

12. An apparatus comprising:
a plasma generating chamber;
a showerhead adjacent to the plasma generating chamber, the showerhead having an upper surface and a lower surface, the showerhead having a first array of holes that extend from the upper surface to the lower surface, the upper surface of the showerhead is the lower electrode of the plasma generating chamber;
a processing chamber, the lower surface of the showerhead is an upper surface of the processing chamber; and
a pedestal within the processing chamber for supporting a substrate adjacent to the lower surface of the showerhead.

13. The apparatus of claim 12 further comprising:
an RF power source coupled to a lower surface of the showerhead;
wherein the pedestal is grounded.

14. The apparatus of claim 12 wherein the pedestal includes a cooling mechanism for keeping a substrate placed on the pedestal below 100° C. during processing.

15. The apparatus of claim 12 wherein the showerhead includes an internal volume between the upper surface and the lower surface, an inlet hole to the internal volume and a second array of holes in the lower surface for the second process gas to flow to the processing chamber.

16. The apparatus of claim 12 wherein the upper electrode of the plasma generating chamber is a blocker plate for distributing the first processing gas.

17. The apparatus of claim 12 further comprising:
a spacer ring between the upper electrode and the lower electrode, the spacer ring is dielectric and thermally conductive.

18. The apparatus of claim 12 further comprising:
a spacer ring between the upper electrode and the lower electrode, the spacer ring is dielectric and a thermally insulative.

19. The apparatus of claim 12 further comprising:
a spacer ring between the upper electrode and the lower electrode; and
a heater coupled to or embedded within the spacer ring.

20. The apparatus of claim 12 further comprising:
a heater coupled to the plasma generating chamber.

21. The apparatus of claim 12 further comprising:
a plurality of holes that extend vertically through the showerhead, the holes have a depth to width ratio that is more than 5:1.

22. The apparatus of claim 12 further comprising:
a spacer ring between the upper electrode and the lower electrode; and
a plurality of holes that extend vertically through the spacer ring, the holes have a depth to width ratio that is more than 5:1.
